(19) United States
(12) Patent Application Publication
(10) Pub. No.: US 2008/0303530 A1
(43) Pub. Date: Dec. 11, 2008

(54) Electrostatic Sensor

(75) Inventors: Constantin Coutsornitros, Ranco (IT); Christophe Korn, Mol (BE)

Correspondence Address: CANTOR COLBURN, LLP, 20 Church Street, 22nd Floor, Hartford, CT, 06103, US

(73) Assignee: THE EUROPEAN COMMUNITY, Brussels (BE)

(21) Appl. No.: 12/158,940

(22) PCT Filed: Dec. 15, 2006
(86) PCT No.: PCT/EP2006/069787

§ 371 Date: Jun. 23, 2008

(30) Foreign Application Priority Data
Dec. 23, 2005 (EP) 051129757
Dec. 23, 2005 (EP) 051129773

(51) Int. Cl. G01R 29/12

(52) U.S. Cl. 324/457

(57) ABSTRACT

An electrostatic sensor generally includes a sensor head with at least one passive sensing electrode responsive to an electric field and a high-impedance amplification stage associated with the sensing electrode. The high-impedance amplification stage is configured for outputting at least one output signal in response to an electric signal induced on the at least one sensing electrode by the electric field. The sensor head further includes a screen of electrically insulating material, which is associated with the at least one sensing electrode. In an operational mode of the electrostatic sensor, the screen is electrically charged and induces an electric field in the surroundings of the sensing electrode.

### TECHNICAL FIELD OF THE INVENTION

The present invention generally relates to the sensing of electric fields in the regime commonly referred to as “electrostatics” and in particular to an extremely sensitive electrostatic sensor.

### BRIEF DESCRIPTION OF RELATED ART

The field of electrostatics, which concerns itself with electrical charges, potentials and forces, has first been studied in the 18^{th} and 19^{th} centuries. The most important instruments for exploring the world of electrostatics are electroscope or electrometer.

An electroscope usually comprises two thin gold leaves suspended from an electrical conductor inside an electrically insulating container. The electrical conductor is connected to an electrode outside the container. The electroscope indicates the presence of a charged body by the gold leaves standing apart at a certain angle. A charged body, which is brought close to or in contact with the electrode induces or transfers a like electric charge to each gold leaf, which in consequence repel each other.

An electrometer is usually an elaborate variant of a voltmeter with a very high input impedance (up to the order of 10¹⁵ Ohms). Such an electrometer can be used for remotely sensing any electrically charged object. It is not possible, however, to sense uncharged, i.e. electrically neutral bodies.

### BRIEF SUMMARY OF THE INVENTION

The invention to provides an electrostatic sensor capable of remotely sensing uncharged electrically conductive bodies.

An electrostatic sensor generally comprises a sensor head with at least one passive sensing electrode responsive to an electric field and a high-impedance amplification stage associated with the sensing electrode. The high-impedance amplification stage is configured for outputting at least one output signal in response to an electric signal induced on the at least one sensing electrode by the electric field. According to an important aspect of the invention, the sensor head comprises a screen of electrically insulating material, which is associated with the at least one sensing electrode. In an operational mode of the electrostatic sensor, the screen is electrically charged and induces an electric field in the surroundings of the sensing electrode. It has been surprisingly found that by the presence of the charged screen, the electrostatic sensor can be used to detect conductive, uncharged objects, which are in movement with respect to the sensor head or the sensing electrode. The charged screen electrostatically induces a separation of positive and negative charges in the conductive object, which has an effect on the surrounding electric field. When the sensor head is moved with respect to the conductive object, this effect can be detected. As shall be noticed, the sensor is passive in the sense that it does not include an excitation electrode, which applies an alternative electromagnetic field to be sensed by a receiving electrode.

It will be appreciated that the electrostatic sensor can be used for detecting an electrically uncharged conductive body at rest in a target region. To this effect, the sensor head is moved with respect to the target region and spatial variations of the electric field are sensed so as to locate the electrically uncharged conductive body, e.g. a metal landmine. Similarly, the electrostatic sensor can be used for detecting an electrically uncharged conductive body moving in a target region. In this case, one preferably keeps the sensor head at rest with respect to the target region and senses the spatial variations of the electric field so as to locate the electrically uncharged conductive body.

The impedance and the amplification factor of the electrostatic sensor can be chosen such that currents in the sensing electrode of the order of 10⁻¹⁷ Amperes can be measured. Preferably, the gain and/or the input impedance can be adjusted, e.g. by means of a rotary-type switch. As shall be noted, the sensitivity of the system also increases if the electric charge of the screen of electrically insulating material increases.

Preferably, the electrostatic sensor comprises a grounded reference electrode connected to the amplification stage.

The sensing electrode can have a variety of forms, e.g. rectangular, circular, cylindrical, etc. Preferably, however, the sensing electrode comprises a stick electrode or a plate electrode. The material of the sensing electrodes may be any good conductor, e.g. copper, gold, silver, aluminium, nickel, etc. It will be appreciated that the sensor's sensitivity increases with the size of the sensing electrode. In the case of a stick electrode, the insulating screen advantageously comprises a tubular screen arranged coaxially around the electrode, e.g. a plastic drinking-straw. It will be appreciated that the charged layer can be movably or removably mounted on the sensor head. The electrostatic sensor can hence easily be used in two different modes: first, for the extremely sensitive detection of uncharged conductors and second, for the extremely sensitive detection of charged objects.

According to a preferred embodiment of the invention, the electrostatic sensor further includes a processing unit operationally connected to the amplification stage for analysing the sensed electric field. In particular, the amplification stage or the processing unit can comprise an analog-to-digital converter unit for digitizing the amplified signals.

According to a further embodiment of the invention, the electrostatic sensor comprises a plurality of passive sensing electrodes. The amplification stage is configured so as to output a plurality of output signals, each one of these output signals being in response to an electric signal induced on a respective sensing electrode. Such an electrostatic sensor can, for instance, be used for tracking the movement of an uncharged, conductive object. The movement of the conductive object can be determined by triangulation methods. The distance from the object to each electrode can be obtained by comparing the amplitudes of the signals induced in the electrodes. The number of electrodes required for following the movement may depend on the degrees of freedom of the object in movement.

According to yet another embodiment of the invention, the sensing electrodes are arranged in a matrix-like configuration, wherein the distance between the electrodes is substantially smaller than the objects to be detected/and or imaged. With such a sensor, a two-dimensional image of an electric field can be produced. Advantageously, it includes a processing unit connected to the amplification stage for producing the 2D-image of the electric field and/or means for displaying information related to said electric field. In some embodiments of the invention, the matrix is rectangular but it could also be hexagonal.

An application of an electrostatic sensor is, for instance, the contactless sensing of vibrations. By means of a sensing electrode matrix, two-dimensional images of vibrational modes can be contactlessly obtained.

It will furthermore be highly appreciated that the electrostatic sensor can be used for recording an electroencephalogram or an electrocardiogram. This is done without applying electrodes on the patient's skin, which constitutes a considerable advantage over the traditional technique. The sensor head can be configured as a hood with the sensing electrodes distributed over its inner surface. Consequently, a map of the patient's cerebral activity can be provided.

Another useful application of the electrostatic sensor is the contactless detection of an electric signal in a cable or wire. As will be appreciated, even a shielded cable or wire can be eavesdropped with a sufficiently sensitive electrostatic sensor.

The skilled person will appreciate that the electrostatic sensor can be used for detecting landmines, especially low-metal landmines, e.g. by applying the methods above. Today, the most widely used tool for humanitarian demining is the metal detector. The principal drawbacks of metal detectors are the high false alarm rate and the difficulty of finding low-metal mines, e.g. mines composed of less than 0.5% of metal. In this context one may note that for about 20 years, almost all antipersonnel mines produced have been low-metal mines. Since mines are mostly composed of metal and plastic (besides of explosives) a plastic detector constitutes a good alternative or complementary detector for finding mines. Indeed, one can also integrate both metal and plastic detectors in a single mine detector. A landmine detector may for instance comprise an electrostatic field imager (i.e. an electrostatic sensor having the sensing electrodes arranged as a matrix) with a movable or removable plastic screen, which can be electrostatically charged and brought in front of the sensing electrodes. When the plastic screen is moved aside or completely removed, plastic objects can be detected, when it is in place, metal objects can be detected. It will highly be appreciated that the electrostatic field imager provides at least a coarse image of the object sensed, thus allowing determination of size and shape of the object.

Another interesting application of an electrostatic sensor is the in-vivo detection of a ruminal bolus ingested by a living being. Ruminal boluses are currently used for electronically identifying ruminants. A ruminal bolus is usually constituted by a body having an electronic device for storing and interchanging data, such as a passive RFID transponder unit, which is encapsulated in a capsule presenting a high resistance to the digestive juices and to the processes that take place in the pre-stomachs of ruminants. Materials used for fabricating the capsule include resins, high-density glasses, or materials based on alumina or silica. For identification of the animal, a reading device sends a query signal to the RFID transponder, which in turn emits a response signal containing some information about the ruminant, e.g. an identification code. In some cases, however, there is no response from the RFID transponder unit. Authorities my have an interest in determining if the bolus has intentionally not been put into place or if it is malfunctioning. To find out whether the RFID transponder has a defect or the bolus is not in place, there are presently two options, namely radiography with X-rays or post-mortal examination. Both methods involve prohibitive costs and are not suited for systematic testing. Detecting a bolus with an electrostatic sensor is a viable alternative, as it is non-lethal and involves reasonable costs.

### BRIEF DESCRIPTION OF THE DRAWINGS

Preferred embodiments of the invention will now be described, by way of example, with reference to the accompanying drawings in which:

FIG. 1: is a perspective view of a setup for the detection of the movement of an uncharged conductive object;

FIG. 2: is a perspective view of a setup for the detection of a movement in three dimensions of an uncharged conductive object;

FIG. 3: is an illustration of the use of an electrostatic sensor for recording an electroencephalogram;

FIG. 4: is a perspective view of an experimental setup with an electrostatic sensor adapted for spatially resolved detection of uncharged conductive objects;

FIG. 5: is a perspective view of an experimental setup with an alternative electrostatic sensor adapted for spatially resolved detection of unconductive objects;

FIG. 6: is a simplified block diagram of the electrical circuits of the electrostatic sensors of FIGS. 4 and 5;

FIG. 7: is a block diagram illustrating the contactless detection of signals in a shielded cable.

FIG. 8: is a perspective view of an alternative embodiment of a sensor head for an electrostatic sensor;

FIG. 9: is an illustration of an electrostatic imager used for ruminal bolus detection;

FIG. 10: is a perspective view of a landmine detector comprising an electrostatic field imager.

### DETAILED DESCRIPTION OF THE INVENTION

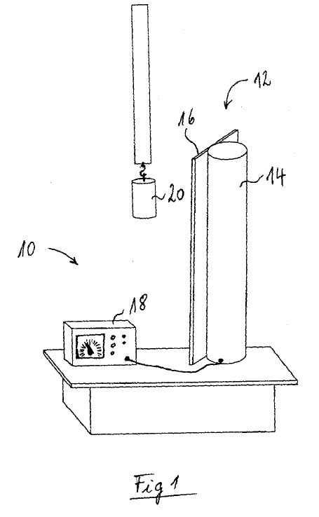

FIG. 1 shows an experimental setup illustrating the detection of a movement of a conductive object by means of an electrostatic sensor 10. The electrostatic sensor comprises a sensor head 12 with a passive cylindrical metal sensing electrode 14, which is at rest with respect to a reference system (corresponding in this case to the lab room). The sensor head 12 also comprises an electrically charged plastic screen 16, which is tangent to the cylindrical sensing electrode 14. In this case, the plastic screen 16 is arranged between the object to be sensed and the sensing electrode 14. The sensing electrode 14 is electrically connected to an electrometer 18 integrating a high-impedance amplification stage, preferably with variable amplification. Alternatively, the sensing electrode can also be connected to a computer, via the amplification stage and an analog-to-digital converter.

A metal body 20 is suspended from the lab room ceiling and may freely swing. When the metal body 20 moves with respect to the electrode 14, small currents are electrostatically induced in the latter, which can be detected by the electrometer 18. Experiments under lab conditions have shown that currents of 10⁻¹⁷ Amperes can be measured. The sensitivity of the system is extraordinarily high and the achieved precision is comparable to interferometric measurement techniques, with the distance from the electrode 14 and the metal body 20 up to three metres.

The electrostatic sensor of FIG. 1 can also be used for detecting vibrations of any conductive structure, e.g. an engine or a wall in proximity of an engine. In contrast to acceleration sensors, the electrostatic sensor needs not being in contact with the object that vibrates. This constitutes a considerable advantage, as any additional mass on the object alters its resonance frequencies changes the measurement.

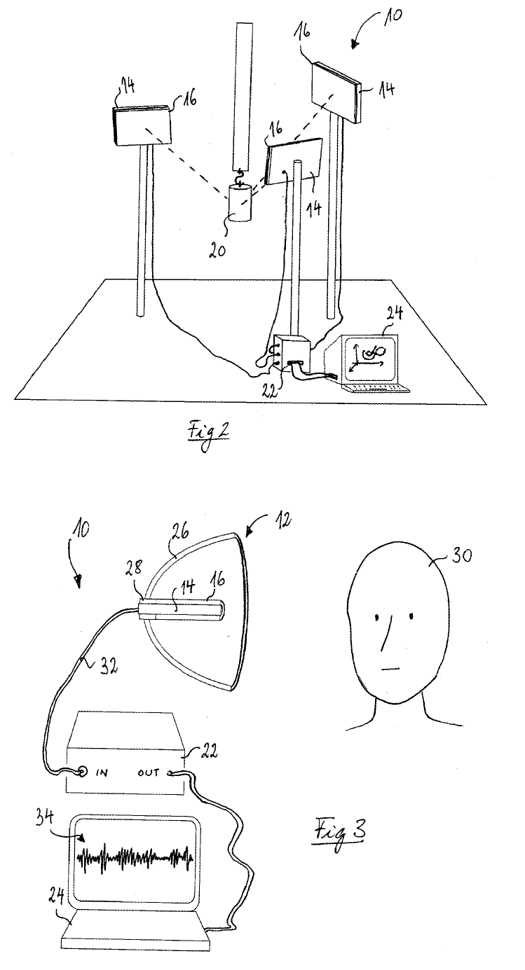

FIG. 2 shows another experimental setup illustrating the tracking of an object in three dimensions. The electrostatic sensor 10 comprises in this case three passive metal-plate sensing electrodes 14, each one covered with a plastic screen 16. The sensing electrodes are electrically connected to a high-impedance amplification stage 22, which converts the electrical currents electrostatically induced on in the electrodes 14 to output signals. The output signals are passed on to a computer 24, which is equipped with an analog-to-digital converter. The computer 24 analyses the output signals of the amplification stage 22 and determines the position of the metal body 20 by triangulation, i.e. by calculating the distance of the metal body to each sensing electrode 14. The movement of the metal body is displayed in real time on the computer screen and stored in memory for later analysis.

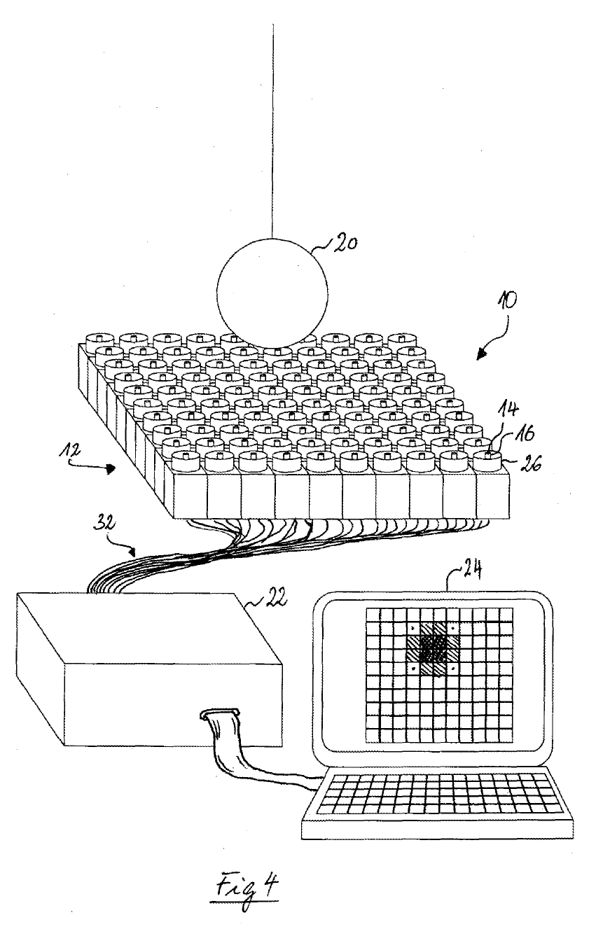

FIG. 3 illustrates the use of an electrostatic sensor 10 for recording an electroencephalogram. The sensor head 12 is shown in a cross-sectional view. The sensor head 12 comprises a stick-like sensing electrode 14, which is arranged on the axis of a grounded paraboloidal reference electrode 26. The sensing electrode 14 is fixed to the reference electrode 26 with an insulating mounting 28. The sensing electrode 14 is covered with a tubular plastic screen 16, which has been electrically charged prior to the measurement. The sensor head 12 is oriented towards a patient's head 30. It should be noted that other sensor head configurations, especially regarding the form of the sensing electrode or the reference electrode can be used.

The sensing electrode 14 is connected to a high-impedance amplification stage 22 with a shielded cable 32. The amplification stage amplifies the signals received on the sensing electrode and outputs corresponding output signals. A computer 24, which includes an analog-to-digital converter, records and analyses the output signals of the amplification unit 22 and visualizes the recorded data 34. The electrostatic sensor remotely senses the surface electric potentials caused by the currents flowing in the patient's head.

The setup illustrated in FIG. 3 allows the recording of a patient's electroencephalogram but it will be appreciated that the sensor head could also be directed to other regions of the patient's body, e.g. the chest for recording an electrocardiogram. A plurality of sensing electrodes may also be used. The measurement method does not require contacting the patient with paste-on electrodes. It shall be emphasised that the sensitivity of the system is greatly enhanced by the screen of electrically charged, insulating material. Furthermore, if the electric charge of the screen increases, the sensitivity of the system increases. By increasing the electric charge of the screen, one may reduce the amplification factor of the high-impedance amplification stage or increase the distance between the patient and the sensing electrode(s).

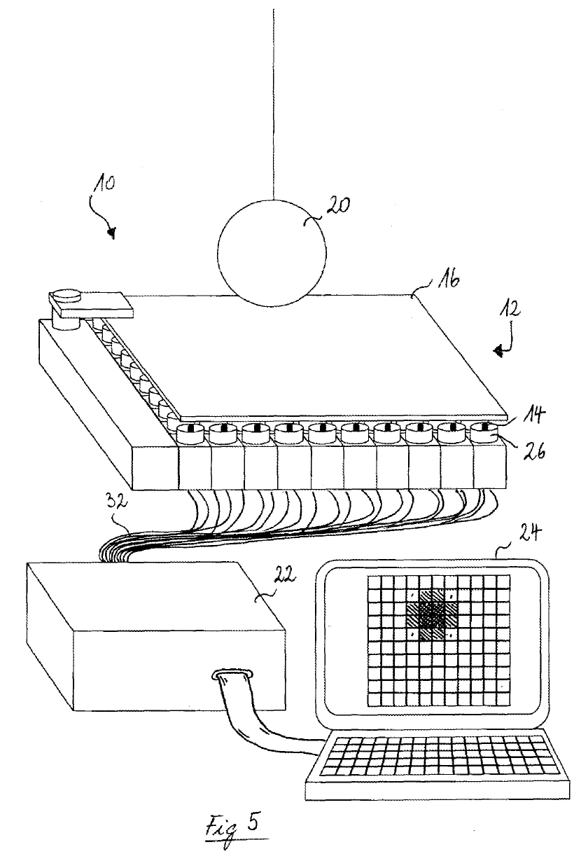

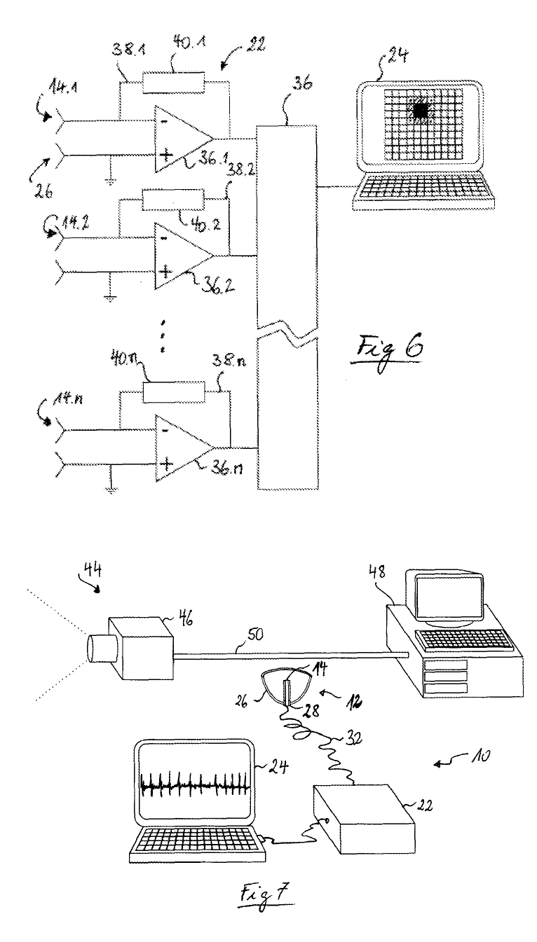

FIGS. 4 and 5 show an experimental setup with an electrostatic sensor 10 adapted for spatially resolved detection of uncharged conductive objects. A metal body 20 is suspended from the ceiling and its movements are to be detected by the electrostatic sensor 10. The sensor head 12 comprises a 10×10 array of sensing electrodes 14. In the embodiment of the electrostatic sensor shown in FIG. 4, each sensing electrode 14 is covered with a charged electrically insulating tubular plastic screen. In the alternative embodiments of FIG. 5, a charged plane plastic screen 16, common to all the sensing electrodes 14, is arranged between the sensing electrodes and the object to be detected. The plastic screen 16 can be moved from its operational position in front of the sensing electrodes to an inactive position. In its inactive position, the plastic screen 16 is not arranged in front of the sensing electrodes. Switching between operational and inactive positions can be achieved by rotating the plastic screen 16 around an axis outside the matrix of the sensing electrodes 14. With the plastic screen 16 in its inactive position, the electrostatic sensor 10 can be used for detection of electrostatically charged objects. Grounded reference electrodes 26 are arranged laterally around the sensing electrodes 14. The sensing electrodes 14 are electrically connected to amplification circuits inside the amplification unit 22. The signals of sensing electrodes 14 are separately provided to the amplification unit by shielded cables 32 (not all of them shown in the figures) and amplified by an adjustable factor. The input impedance of the amplification circuits is extremely high (up to 10¹⁵ Ohms), so that virtually no current is drawn from the sensing electrodes 14. The amplified signals are provided to a multiplexer 42 (see FIG. 6), which produces a multiplexed output signal. The multiplexed output signal is provided to a computer 24, which analyses the received signals. Depending on the application, the computer can display an image of the received signal amplitudes, store the amplitudes in memory and/or identify certain patterns in the image.

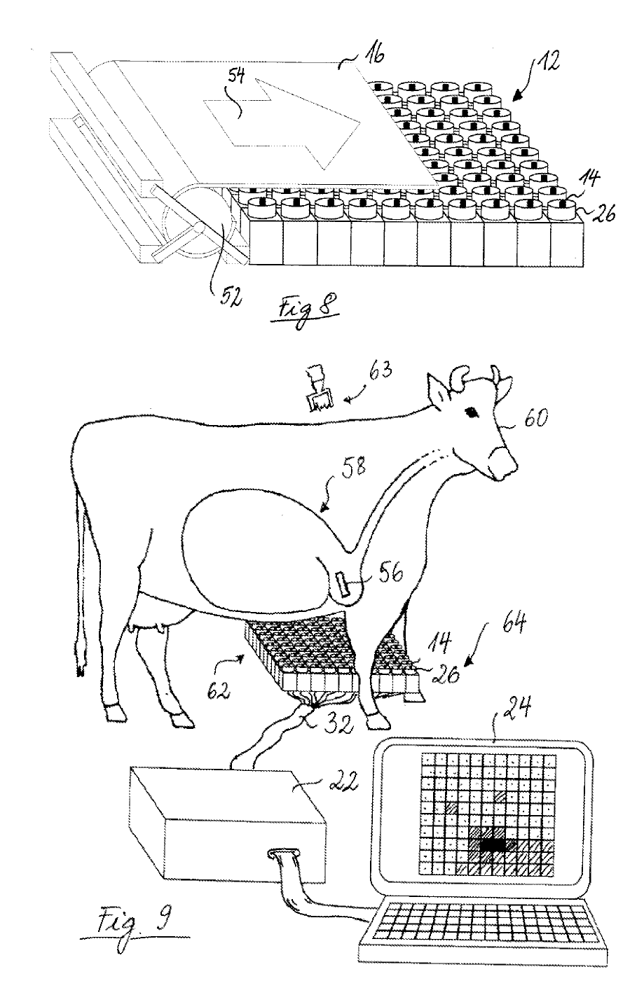

The sensor head 12 may comprise an electric motor, which drives the plastic screen 16 from its operational to its inactive position. The plastic screen 16 can also be achieved as a curtain (see FIG. 8), which is rolled up on a cylinder 52 in its inactive position and which can be moved, manually or automatically, over the sensing electrodes 14 along the direction indicated by arrow 54. The plastic may be chosen such that the rolling off from the cylinder 52 creates the electrostatic charges on the plastic screen 16. An additional charging step could then be omitted.

For detecting the uncharged metal body 20, the sensor head 12 is in movement with respect to the metal body 20. The skilled person will appreciate that it can actually be the metal body 20 that moves while the sensor head 12 is at rest.

Electrostatic sensors like those of FIGS. 4 and 5 can for instance be used for imaging the modes of a vibrating object, e.g. an engine. With its extremely high impedance, displacements of conductive structures can be remotely detected in the sub-micrometer range.

It shall further be noted that the electrostatic sensor matrix may be used for recording a spatially resolved electroencephalogram or electrocardiogram. A two-dimensional map of the brain or heart activity may thus be obtained.

In certain cases, it may prove useful if the sensing electrodes are arranged on a curved surface, for example on the inner side of a hood, which is put over a patient's head for taking an electroencephalogram at several points of the head. As the sensing electrodes need not being in contact with the patient's skin, there can be a spacing structure, which keeps them at a defined distance from the head. Air may thus circulate between the sensing electrodes and the head, which greatly enhances the patient's comfort during the measurement as sweating may for instance be reduced.

A simplified block diagram of the electrical circuits of an electrostatic sensor as in FIGS. 4 and 5 is shown in FIG. 6. A plurality of passive sensing electrodes 14.1, 14.2, . . . , 14.n (n being a positive integer) are connected to an amplification stage 22, which comprise at least one first low-noise operational amplifier 36.1, 36.2, . . . , 36.n associated with each sensing electrode 14.1, 14.2, . . . , 14.n. In certain embodiments, the output of the first low-noise operational amplifier is connected to an input of a second low-noise operational amplifier. It will be appreciated that the signals on the sensing electrodes 14.1, 14.2, . . . , 14.n are amplified individually. The ultrahigh impedance of the amplification stage is achieved by the feedback loops 38.1, 38.2, . . . , 38.n. The gain can be adjusted by changing the resistance 40.1, 40.2, . . . , 40.n of the feedback loops 38.1, 38.2, . . . , 38.n; preferably, the system comprises a switch or an automated system for adjusting the gain to an optimal value, depending on the amplitude of the sensed signal. After amplification, the signals are fed to a multiplexer 42, which preferably operates at a rate above 30 Hz, still more preferably between 50 to 100 Hz. Advantageously, the circuits comprise a filtering stage, which eliminates undesired frequency components, like for instance the 50-Hz- or 60-Hz-peak caused by mains. Such a filtering stage may be integrated into the multiplexer 42. The multiplexed signal is fed to a computer 24, which is equipped with an analog-to-digital converter and wherein the signal is demultiplexed. The individual signals of the sensing electrodes can thus be retrieved, analysed, displayed and/or stored in memory.

FIG. 7 illustrates the contactless detection of signals in a shielded communication cable. In a video surveillance system 44, a digital camera 46 is connected to an input port (e.g. RS 485 serial port) of a control computer 48 via a shielded communication cable 50. An electrostatic sensor 10 is provided for contactlessly eavesdropping the communication between the camera 46 and the control computer 48. The sensor head 12 is brought into proximity of the communication cable 50. The sensor head 12 may e.g. be a smaller version of the sensor head shown in FIG. 3 and will not be described in detail again. It shall be noted, however, that other sensor head configurations could also used for the present purpose. The sensor head 12 is connected to the high-impedance amplification stage 22, which feeds the amplified signals to the computer 24.

In the present case, the communication signal transmitted between the camera 46 and the control computer 48 is assumed to be of square-wave type. The signals measured by the electrostatic sensor 10, which are shown in an exemplary fashion on the screen of the computer 24, are usually not of square-wave type. The intervals between the detected electrostatic peaks correspond to those of the original communication signal. By convolution of the electrostatic signal with a square-wave function, it is possible to retrieve the original communication signal. The electrostatic sensor thus can detect the communication signals either emitted by the camera to the computer or vice versa.

The electrostatic sensor 10 can also be used to detect the electric signals inside an electronic appliance, e.g. a computer or a camera. For instance, if the sensor head 12 is brought into proximity of the camera 46, electric activity of the latter can remotely be detected. From the signal detected by the electrostatic sensor 10, one can draw certain conclusions, for instance, it is possible to determine the recording interval of the camera 46 or to eavesdrop on data exchanges inside the camera by using e.g. Fourier or wavelet analysis methods.

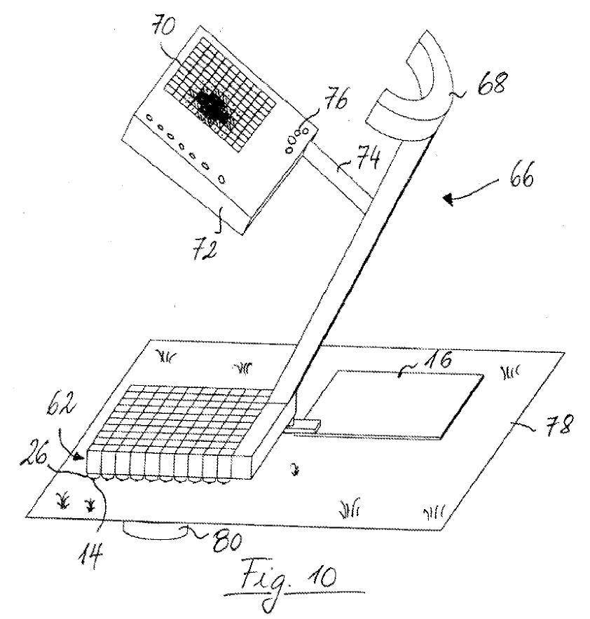

FIG. 9 illustrates the use of an electrostatic field imager (e.g. as in FIG. 4) for detecting a ruminal bolus. In order to detect the presence of a dysfunctional ruminal bolus 56 in the digestive tract 58 of a ruminant 60, a sensor head 62 of an electrostatic field imager 64 is arranged next to the ruminant's body, and an electric field is generated at or from behind the ruminant's body, e.g. by creating a small electric discharge behind the ruminant or on the ruminant as shown at 63. The term “behind” is used here with respect to the electrostatic field imager. As the bolus 56 contains a certain amount of electrically insulating material, it alters the electric field caused by the discharge, which can be detected by the electrostatic field imager 64. The bolus normally consists an elongated substantially cylindrical capsule of about 7 cm long and about 2 cm in diameter. When an insulating object is detected inside the ruminant 60, the sensor head 62 can be moved in order to determine the shape of the detected object under different angles. From these observations, it can be easily concluded with high certainty whether the detected object is a ruminal bolus or not.

FIG. 10 illustrates the use of an electrostatic imager for detecting landmines. First, one has to understand that electrostatic charges remain a long time on the plastic parts of a mine, especially if the soil is dry. The electrostatic field created by these charges can be detected by an electrostatic field imager as described above.

The situation may nevertheless occur that the plastic parts of a mine wear less than a detectable amount of electrostatic charges. It is therefore recommended, especially for humid soil, to first apply an electrostatic discharge to the area that is to be scanned. This can be done by approaching to the ground an electrode at a high electric potential or by using a stun gun (delivering electric discharges of the order of 10⁵ V).

Experiments with dummy mines have shown that even mines, which had been covered with a metal plate can be reliably detected by means of the electrostatic field imager. As a matter of fact, the field created by the electrostatic charges on the mine is not completely stopped at the metal plate due to imperfect grounding. One thus observes an attenuation of the signals on the sensing electrodes, but detection is still possible.

The landmine detector 66 comprises an integrated electrostatic field imager. The shaft of the battery-powered detector 66 has an armrest 68 on its first end and a sensor head 62 on its second end, which is opposed to the first end. The sensor head comprises a sensing electrode matrix, which faces the ground when the detector is in use. In this case, the matrix is rectangular with ten rows and ten columns, but these numbers and the shape of the matrix may vary. A grounded reference 26 electrode is arranged laterally around each sensing electrode 14. The landmine detector 66 further comprises an amplification stage for amplifying the signals of the sensing electrodes and an A/D converter for digitizing the amplified signals. A processing unit is integrated into the detector 66, which analyses the digitised signals. A display 70 is included, which provides in real time a 2D-image of the sensed electric field. As shown in FIG. 6, the display 70 can be an LCD integrated into a control unit 72 on the detector handle 74, by which the detector 66 can be carried. Preferably, the most used control buttons 76 are located on the handle or next to it on the control unit 72 in such a way that the user can actuate them with only one hand, e.g. with the thumb. Those skilled will appreciate that the display 70 could also comprise an a matrix of LEDs, which probably makes the mine detector 66 more affordable and lighter. Moreover, the display 70 can be arranged on the upper side of the sensor head 62.

The sensor head 62 comprises an additional plastic screen 16 rotatably mounted thereon. The plastic screen 16 can be brought into an active position, where it is located between the sensing electrodes and the ground 78 or in an inactive position. In its active position, the plastic screen can be electrostatically charged, which enables the landmine detector 66 to detect buried conductive bodies, in particular the metal parts of a mine.

The handling of the present landmine detector 66 is very similar to metal detectors commonly used for de-mining. The user swings the sensor head 62 at more or less constant speed in small arcs over the track he intends to take. The detection principle is the same as above: when the sensing electrodes move with respect to the electrostatically charged plastic parts of a mine 80, currents are induced in the sensing electrodes 14, which can be measured and used for providing an image of the electric field. This image can be directly displayed so that the user may immediately decide whether the detected electric field is caused by a mine 80. In order to facilitate the user's task, the detector 66 preferably comprises a discriminator, which analyses the structures of the detected electric field, for instance by comparing these structures with stored ones in a database. In case one of the stored structures matches an actually detected structure, the detector can emit an audible and/or visible alarm. Preferably, the discriminator takes into account environmental conditions, such as humidity, temperature, soil consistency, etc.

The user can perform a second sweep over the area in front of him, with the plastic screen 16 in its active position. During the second sweep, metal parts are detected. The combined results of the two sweeps constitute an improved basis for evaluating the situation. In elaborate versions of the mine detector 66, the processing unit may be able to automatically combine the images of the two sweeps.

It will be appreciated that the electrostatic field imager can be combined with other mine detection devices for increasing their reliability.

1. An electrostatic sensor comprising:
a sensor head with at least one passive sensing electrode responsive to an electric field; and
a high-impedance amplification stage associated with said at least one sensing electrode, said high-impedance amplification stage being configured so as to output at least one output signal in response to an electric signal induced on said at least one sensing electrode by said electric field;
and wherein
said sensor head comprises a screen of electrically insulating material associated with said at least one sensing electrode, said screen being electrically charged in an operational mode of said electrostatic sensor and inducing an electric field in the surroundings of said sensing electrode when the screen is electrically charged.

2. The electrostatic sensor according to claim 1, comprising a grounded reference electrode connected to said amplification stage.

3. The electrostatic sensor according to claim 1, wherein said at least one sensing electrode comprises a stick electrode.

4. The electrostatic sensor according to claim 3, wherein said screen comprises a tubular screen arranged around said stick electrode.

5. The electrostatic sensor according to claim 1, comprising a processing unit operationally connected to said amplification stage for analysing said electric field.

6. The electrostatic sensor according to claim 1, wherein said charged layer is removably mounted on said sensor head.

7. The electrostatic sensor according to claim 1, comprising a plurality of passive sensing electrodes arranged in a matrix, and wherein said amplification stage is configured so as to output a plurality of output signals, each one of these output signals being in response to an electric signal induced on a respective sensing electrode.

8. The electrostatic sensor according to claim 7, comprising a processing unit connected to said amplification stage for producing a 2D-image of said electric field.

9-17. (canceled)

18. Method of contactlessly detecting electric signals comprising the use of an electrostatic sensor, wherein said electrostatic sensor comprises:
a sensor head with at least one passive sensing electrode responsive to an electric field; and
a high-impedance amplification stage associated with said at least one sensing electrode, said high-impedance amplification stage being configured so as to output at least one output signal in response to an electric signal induced on said at least one sensing electrode by said electric field;
and wherein said sensor head comprises a screen of electrically insulating material associated with said at least one sensing electrode, said screen being electrically charged in an operational mode of said electrostatic sensor and inducing an electric field in the surroundings of said sensing electrode when the screen is electrically charged.

19. The method according to claim 18, wherein said signals represent vibrations of an object.

20. The method according to claim 18, wherein said electric signals represent an encephalogram and wherein said encephalogram is recorded.

21. The method according to claim 18, wherein said electric signals represent an electrocardiogram, and wherein said electrocardiogram is recorded.

22. The method according to claim 8, wherein said electric signals represent electric signals in a cable.

23. The method according to claim 18, wherein said electric signals represent a movement with respect to said sensor head of an electrically uncharged conductive body.

24. The method according to claim 18, wherein said electrostatic sensor comprises a plurality of passive sensing electrodes arranged in a matrix, wherein said amplification stage is configured so as to output a plurality of output signals, each one of these output signals being in response to an electric signal induced on a respective sensing electrode, wherein said electrostatic sensor comprises a processing unit connected to said amplification stage for producing a 2D-image of said electric field.

25. The method according to claim 24, comprising using said electrostatic sensor for detecting landmines.

26. The method according to claim 24, comprising using said electrostatic sensor for in-vivo detection of a ruminal bolus ingested by a living being.
